(19) United States
(12) Patent Application Publication
(10) Pub. No.: US 2026/0341369 A1
(43) Pub. Date: Oct. 29, 2026

(54) MEMORY DEVICE AND DATA ACCESSING METHOD THEREOF

(71) Applicant: MACRONIX International Co., Ltd., Hsinchu (TW)

(72) Inventors: Yu-Wei Huang, Taichung City (TW); Shuo-Nan Hung, Hsinchu County (TW); Shin-Jang Shen, HsinChu County (TW)

(73) Assignee: MACRONIX International Co., Ltd., Hsinchu (TW)

(21) Appl. No.: 19/188,004

(22) Filed: Apr. 24, 2025

(51) Int. Cl. G11C 16/26; G11C 16/04

(52) U.S. Cl. CPC G11C 16/26; G11C 16/0483

(57) ABSTRACT

A memory device and a program method thereof are provided. The memory device is, for example, a three dimensional NAND flash memory circuit, and provides a storage media with high-performance and high-capacity. The data accessing method includes: applying a read voltage to a plurality of selected memory cells during a reading operation, where a plurality of sub-data generated according to write-in data are respectively stored in the selected memory cells; and sensing at least one read current generated by the selected memory cells, and generating readout data according to the at least one read current.

### BACKGROUND

### Technical Field

The disclosure relates to a memory device and a data accessing method thereof, and in particular relates to a memory device and a data accessing method thereof capable of reducing a raw bit error rate (RBER) of data.

### Description of Related Art

In conventional memory devices, data loss often occurs due to several conditions. For example, interference often occurs after a programming/reading cycle, causing the logic value of the data stored in the adjacent memory cells to be destroyed; the charge in the memory cell may cause data errors due to long storage period or temperature changes.

Conventional memory devices often use error-correcting code (ECC) technology to correct erroneous bits. However, in some applications, such as multiply-accumulate (MAC) operations, computation must be performed on the raw data without implementing circuits related to error-correcting code. In such applications, memory devices with low raw bit error rate are essential.

### SUMMARY

A memory device and a data accessing method thereof, which may effectively reduce the phenomenon of readout data errors resulting from incorrect judgment during reading operations, are provided in the disclosure.

The data accessing method includes: applying a read voltage to a plurality of selected memory cells during a reading operation, where a plurality of data generated according to write-in data are respectively stored in the selected memory cells; and sensing at least one read current generated by the selected memory cells, and generating readout data according to the at least one read current.

The memory device of the disclosure includes multiple memory cell blocks, multiple page buffers, and a controller. The page buffers are respectively coupled to multiple global bit lines on the memory cell blocks. The controller is coupled to the memory cell blocks and the page buffers. The controller is configured to execute the above data accessing method.

Based on the above, the memory device of the disclosure stores multiple sub-data generated according to the write-in data in multiple selected memory cells respectively. When performing a reading operation, a read voltage is provided to the selected memory cells, and the stored data is obtained by reading the read current provided by the selected memory cells. This may reduce the possibility of errors in the readout data due to memory cell degradation or misjudgment during the reading process.

### BRIEF DESCRIPTION OF THE DRAWINGS

FIG. 1 is a flowchart of a data accessing method of a memory device of an embodiment of the disclosure.

FIG. 2 is a schematic diagram of a data accessing operation of a memory device of an embodiment of the disclosure.

FIG. 3 is a schematic diagram of a memory device of an embodiment of the disclosure.

FIGS. 4-8 are schematic diagrams of multiple implementations of a data accessing method of a memory device of an embodiment of the disclosure.

### DETAILED DESCRIPTION OF DISCLOSED EMBODIMENTS

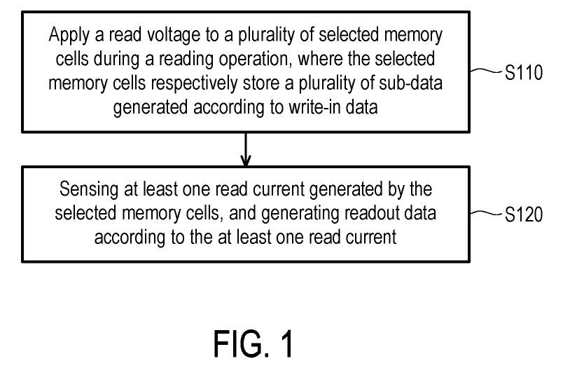

Referring to FIGS. 1,1 is a flowchart of a data accessing method of a memory device of an embodiment of the disclosure. In step S110, the memory device may apply a read voltage to a plurality of selected memory cells during a reading operation, where a plurality of sub-data generated according to write-in data are respectively stored in the selected memory cells, and in step S120, the memory device may sense one or more read currents generated by the selected memory cells, and generate readout data according to the read currents. The memory device may generate the sub-data by duplicating the write-in data, the sub-data and the write-in data may have same logical value.

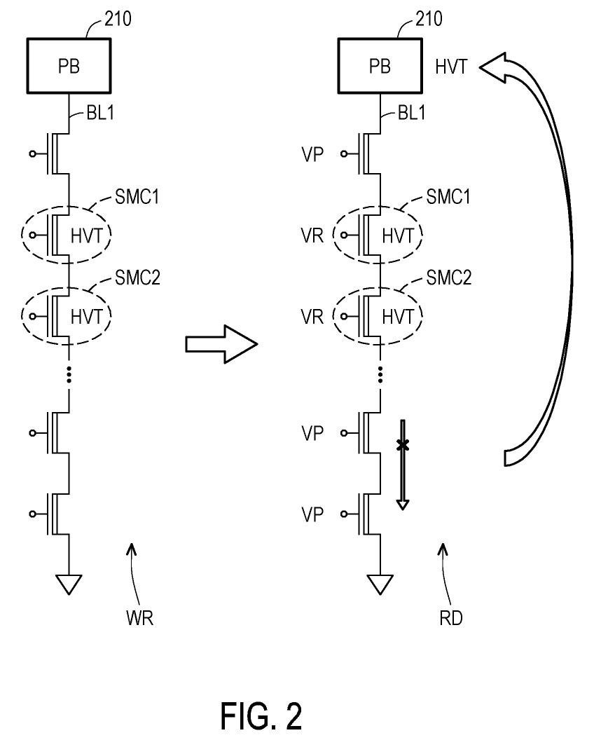

Referring to FIGS. 1 and 2 simultaneously below, FIG. 2 is a schematic diagram of a data accessing operation of a memory device of an embodiment of the disclosure. In the memory device, the page buffer (PB) 210 is coupled to multiple serially connected memory cells through the global bit line BL1. In a writing operation WR, the memory device may duplicate the write-in data of the first logic value into multiple sub-data. Each sub-data may have the same logic value as the write-in data. In this embodiment, the number of sub-data may be two. Next, the memory device may write the sub-data into the selected memory cells SMC1 and SMC2 respectively. In this embodiment, the logic value of the sub-data may be, for example, a logic value 0. The memory device may program the selected memory cells SMC1 and SMC2 to a first threshold voltage state HVT by performing a programming operation on the selected memory cells SMC1 and SMC2 to store write-in data of a logic value 0.

In addition, some selected memory cells (e.g., the selected memory cell SMC1) may be changed to the second threshold voltage state LVT due to interference or degradation, and the threshold voltage thereof may be decreased. During the reading operation RD, in step S110, the memory device may apply a read voltage VR to the word lines of the selected memory cells SMC1 and SMC2, and provide a pass voltage VP to the remaining memory cells. Here, although the selected memory cell SMC1 may be turned on according to the received read voltage VR due to the threshold voltage being changed to the second threshold voltage state LVT, the selected memory cell SMC2 may be cut-off because the threshold voltage thereof maintains the relatively high first threshold voltage state HVT. Therefore, the page buffer (PB) 210 senses the read current on the global bit line BL1 in step S120, and determines that the read current on the global bit line BL1 is less than the first preset threshold. Thus, the page buffer (PB) 210 may obtain the readout data corresponding to the first threshold voltage state HVT, which is the logic value 0, as the correct readout data.

From the above description, it may be known that by writing the sub-data corresponding to the write-in data into the selected memory cells SMC1 and SMC2 coupled in series with each other, when the threshold voltage state of one of the multiple selected memory cells SMC1 and SMC2 is changed from the first threshold voltage state HVT to the second threshold voltage state LVT, the page buffer (PB) 120 may still obtain the correct readout data by sensing the read current jointly provided by the selected memory cells SMC1 and SMC2, thereby effectively reducing the raw bit error rate of the memory device and improving its work performance.

Incidentally, the embodiment of FIG. 2 is applicable to a memory device in which a memory cell is prone to change from a first threshold voltage state HVT to a second threshold voltage state LVT. For example, the memory device of FIG. 2 may be a NAND flash memory device.

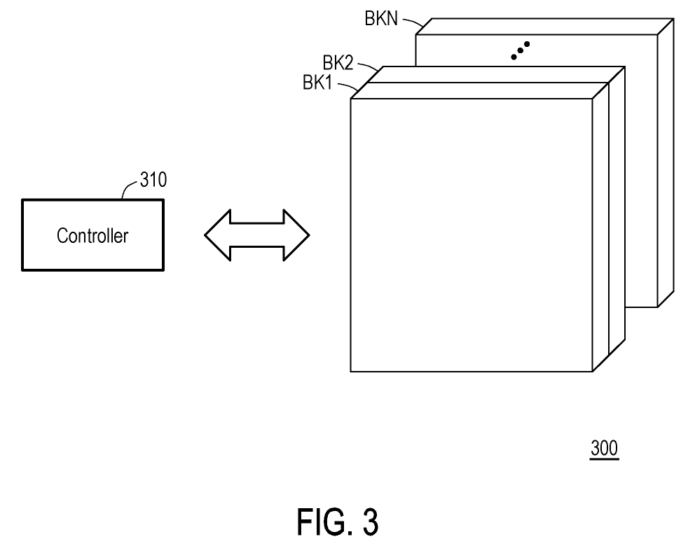

Referring to FIGS. 3 below, 3 , is a schematic diagram of a memory device of an embodiment of the disclosure. The memory device 300 includes a controller 310 and multiple memory cell blocks BK1 to BKN. The memory cell blocks BK1 to BKN are coupled to the controller 310. The controller 310 is configured to control the accessing operations performed on each memory cell block BK1 to BKN. Each of the memory cell blocks BK1 to BKN may include multiple memory cell sub-blocks, and each of the memory cell blocks BK1 to BKN may be NAND flash memory block.

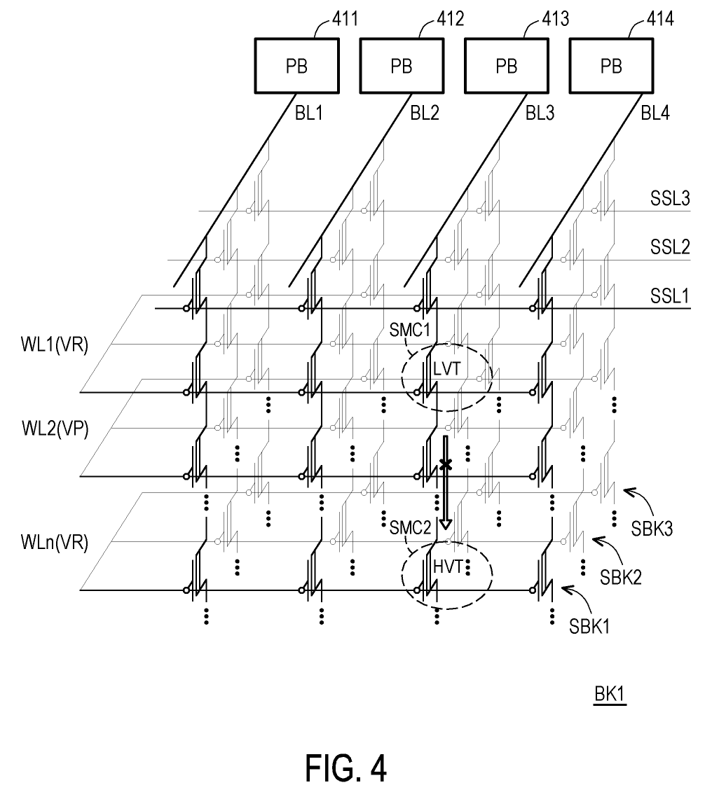

Referring to FIGS. 3 and 4 together below, FIG. 4 is a schematic diagram of an implementation of a data accessing method of a memory device of an embodiment of the disclosure. Taking the memory cell block BK1 in FIG. 3 as an example, in FIG. 4, the memory cell block BK1 may have multiple memory cell sub-blocks SBK1 to SBK3. The memory cell sub-blocks SBK1 to SBK3 correspond to multiple selection signals SSL1 to SSL3 respectively, and are coupled to the same word lines WL1 to WLn. In addition, each of the memory cell sub-blocks SBK1 to SBK3 has multiple memory cell strings, and these memory cell strings are respectively coupled to multiple global bit lines BL1 to BL4. Multiple page buffers (PB) 411 to 414 are respectively coupled to the global bit lines BL1 to BL4.

In this implementation, the number of the selected memory cells SMC1 and SMC2 is, for example, two. The selected memory cells SMC1 and SMC2 may be disposed in the same memory cell sub-block SBK1 in the same memory cell block BK1. Furthermore, continuing the embodiment of FIG. 2, the selected memory cells SMC1 and SMC2 may be coupled in series with each other and coupled to the global bit line BL3 and the page buffer (PB) 413. In this embodiment, the selected memory cells SMC1 and SMC2 may be pre-programmed to be in the first threshold voltage state HVT according to the sub-data of the write-in data. In the reading operation, the word lines WL1 and WLn corresponding to the selected memory cells SMC1 and SMC2 may receive the read voltage VR, and the remaining word line WL2 may receive the pass voltage VP. When the selected memory cell SMC1 changes to the second threshold voltage state LVT, the page buffer (PB) 413 may still obtain correct readout data by sensing the read current on the global bit line BL3 that is lower than the first preset threshold based on the selected memory cell SMC2 still being in the off state.

It is worth noting that the selected memory cells SMC1 and SMC2 may or may not be directly adjacent to each other, and there may be one or more memory cells in between.

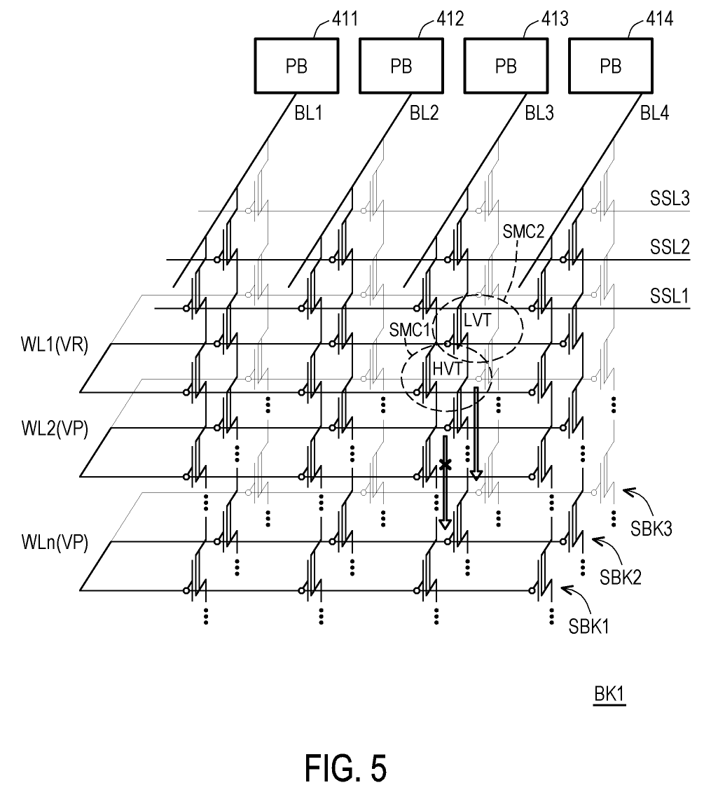

Referring to FIGS. 5 below, 5 is a schematic diagram of another implementation of a data accessing method of a memory device of an embodiment of the disclosure. In this implementation, a single memory cell block BK1 is also taken as an example. The selected memory cells SMC1 and SMC2 may be disposed in the same memory cell block BK1 and respectively disposed in different memory cell sub-blocks SBK1 and SBK2. In this implementation, the write-in data is, for example, a second logic value, and the selected memory cells SMC1 and SMC2 may be erased to a second threshold voltage state LVT according to the sub-data also having the second logic value.

In this implementation, the selected memory cell blocks SMC1 and SMC2 may be coupled to the same global bit line BL3 and coupled to the page buffer (PB) 413. The selected memory cell blocks SMC1 and SMC2 are coupled in parallel to each other and are coupled to the same word line WL1.

When a reading operation is executed, a read voltage VR may be applied to the word line WL1, and a pass voltage VP may be applied to the word lines WL2 and WLn.

If one of the selected memory cell blocks SMC1 and SMC2 (e.g., the selected memory cell SMC1) is changed to the first threshold voltage state HVT, the page buffer (PB) 413 may sense the sensing currents respectively generated by the selected memory cell blocks SMC1 and SMC2 according to the read voltage VR, and determine whether the sum of the sensing currents is greater than the second preset threshold to determine whether the readout data corresponds to the second threshold voltage state LVT.

In this implementation, although the selected memory cell SMC1 is changed to the first threshold voltage state HVT and may be in the off state during the reading operation, the page buffer (PB) 413 may still obtain a sufficiently large sensing current and may determine that the readout data is the second logic value corresponding to the second threshold voltage state LVT, for example, a logic value 1, because the selected memory cell SMC2 is still maintained in the second threshold voltage state LVT and is in the on state.

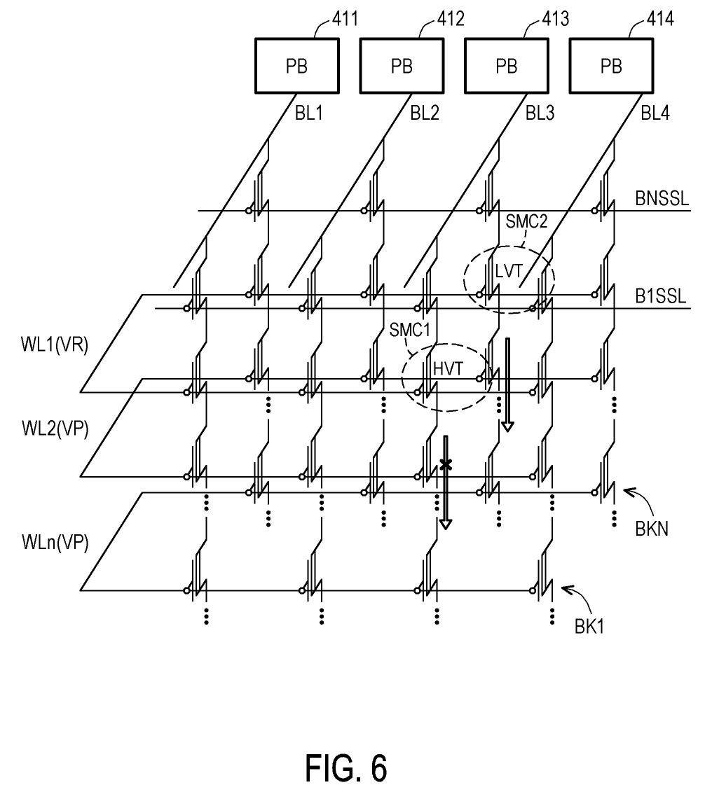

Referring to FIGS. 6 below,6 is a schematic diagram of another implementation of a data accessing method of a memory device of an embodiment of the disclosure. In this implementation, the selected memory cells SMC1 and SMC2 may be respectively disposed in different memory cell blocks BK1 and BKN. The memory cell blocks BK1 and BKN respectively receive the selection signals B1SSL and BNSSL and are respectively activated according to the selection signals B1SSL and BNSSL.

In addition, the selected memory cells SMC1 and SMC2 may be coupled to the same word line WL1. The selected memory cells SMC1 and SMC2 are coupled to the same global bit line BL3, and then coupled to the page buffer (PB) 413 through the global bit line BL3. Similarly, in this implementation, the selected memory cells SMC1 and SMC2 may be coupled in parallel to each other, and similar to the implementation of FIG. 5, when the selected memory cell SMC1 changes to the first threshold voltage state HVT, the buffer (PB) 413 may sense the sensing currents respectively generated by the selected memory cell blocks SMC1 and SMC2 according to the read voltage VR, and determine that the readout data corresponds to the second threshold voltage state LVT by determining that the sum of the sensing currents is greater than the second preset threshold, and obtain correct readout data.

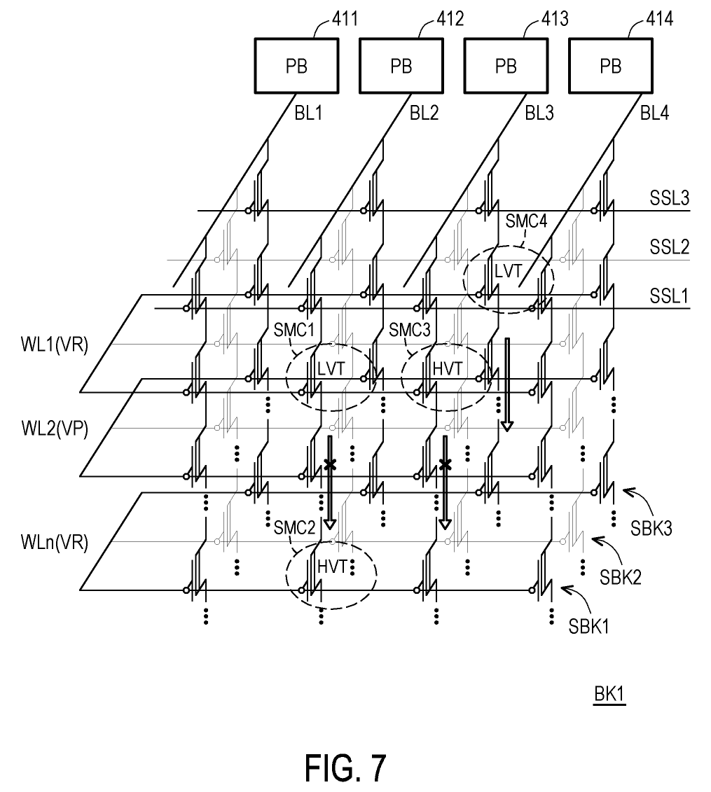

Referring to FIGS. 7 below,7 is a schematic diagram of another implementation of a data accessing method of a memory device of an embodiment of the disclosure. The selected memory cells SMC1 to SMC4 may be disposed together in the same memory cell block BK1. The selected memory cells SMC1 and SMC2 may correspond to the first write-in data, and the selected memory cells SMC3 and SMC4 may correspond to the second write-in data. When the first write-in data is, for example, a logic value 0 (corresponding to a first threshold voltage state HVT), the memory device may perform a programming operation on the selected memory cells SMC1 and SMC2 coupled in series, so that the selected memory cells SMC1 and SMC2 are programmed to the first threshold voltage state HVT. When the selected memory cell SMC1 changes to the second threshold voltage state LVT, the corresponding page buffer (PB) 412 may obtain readout data of logic value 0 by sensing that the read current on the global bit line BL2 is less than the first preset threshold.

Furthermore, when the second write-in data is, for example, logic value 1 (corresponding to the second threshold voltage state LVT), the memory device may perform an erasing operation on the selected memory cells SMC1 and SMC2 coupled in series, and erase the selected memory cells SMC1 and SMC2 to the second threshold voltage state LVT. When the selected memory cell SMC3 changes to the first threshold voltage state HVT, the corresponding page buffer (PB) 413 may obtain readout data of logic value 1 by sensing that the read current on the global bit line BL3 is greater than the second preset threshold.

In this embodiment, the selected memory cells SMC1 and SMC2 may be disposed in the same memory cell sub-block SBK1 of the same memory cell block BK1. The selected memory cells SMC1 and SMC2 may be respectively disposed in different memory cell blocks SBK1 and SBK3 of the same memory cell block BK1. The memory cell blocks SBK1 and SBK3 may be respectively activated according to the enabled selection signals SSL1 and SSL3. In this implementation, the selection signal SSL2 may be in a disabled state.

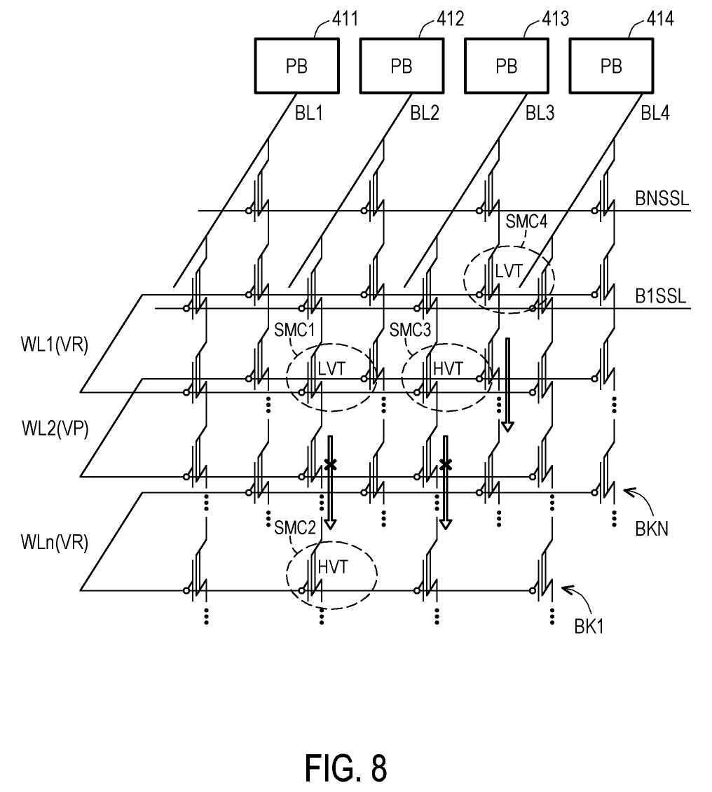

Referring to FIGS. 8 below ,8 is a schematic diagram of another implementation of a data accessing method of a memory device of an embodiment of the disclosure. The operation of the selected memory cells SMC1 to SMC4 is similar to the implementation of FIG. 7, and the same parts are not repeated herein. The difference from the implementation of FIG. 7 is that, in this implementation, the selected memory cells SMC1 and SMC2 may be disposed in the same memory cell block BK1, and the selected memory cells SMC3 and SMC4 may be respectively disposed in different memory cell blocks BK1 and BKN. The memory cell blocks BK1 and BKN may be directly adjacent memory cell blocks or may be non-directly adjacent memory cell blocks, without any specific limitation.

Incidentally, in the embodiment of the disclosure, the data storage operation for a single write-in data may also be performed through three or more selected memory cells. Taking three selected memory cells as an example, the three selected memory cells may be coupled in series or in parallel with each other. Alternatively, two of the three selected memory cells may be coupled in series with each other, and another selected memory cell may be coupled in parallel with one of the two aforementioned selected memory cells. By storing a single write-in data through multiple selected memory cells, the reliability of the data may be further improved, and the possibility of obtaining erroneous readout data in a reading operation may be reduced.

In summary, in this disclosure, write-in data is stored through multiple selected memory cells. By connecting multiple selected memory cells in series or in parallel, the possibility of obtaining erroneous readout data in a reading operation may be reduced, thereby improving the reliability of the readout data.

What is claimed is:

1. A data accessing method of a memory device, comprising:
applying a read voltage to a plurality of selected memory cells during a reading operation, where a plurality of sub-data generated according to write-in data are respectively stored in the selected memory cells; and
sensing at least one read current generated by the selected memory cells, and generating readout data according to the at least one read current.

2. The data accessing method according to claim 1, wherein the sub-data have a same logic value.

3. The data accessing method according to claim 1, wherein the selected memory cells comprise a first selected memory cell and a second selected memory cell, the accessing method further comprises:
disposing the first selected memory cell and the second selected memory cell in a same memory cell sub-block of a same memory cell block, coupling the first selected memory cell and the second selected memory cell to each other in series.

4. The data accessing method according to claim 3, further comprising:
sensing a first read current jointly provided by the first selected memory cell and the second selected memory cell; and
determining the readout data to be a first logic value when the first read current is less than a first preset threshold.

5. The data accessing method according to claim 1, wherein the selected memory cells comprise a first selected memory cell and a second selected memory cell, the accessing method further comprises:
respectively disposing the first selected memory cell and the second selected memory cell in different memory cell sub-blocks of a same memory cell block.

6. The data accessing method according to claim 5, further comprising:
sensing a first read current and a second read current respectively provided by the first selected memory cell and the second selected memory cell; and
determining the readout data to be a second logic value when a sum of the first read current and the second read current is greater than a second preset threshold.

7. The data accessing method according to claim 1, wherein the selected memory cells comprise a first selected memory cell and a second selected memory cell, the accessing method further comprises:
disposing the first selected memory cell and the second selected memory cell in a same memory cell sub-block of a same memory cell block, and respectively coupling the first selected memory cell and the second selected memory cell to different global bit lines.

8. The data accessing method according to claim 1, wherein the selected memory cells comprise a first selected memory cell and a second selected memory cell, the accessing method further comprises:
respectively disposing the first selected memory cell and the second selected memory cell in different memory cell blocks.

9. The data accessing method according to claim 1, wherein the selected memory cells comprise a first selected memory cell, a second selected memory cell, and a third selected memory cell, the accessing method further comprises:
connecting the first selected memory cell and the second selected memory cell in series and disposing the first selected memory cell and the second selected memory cell in a same memory cell sub-block of a same first memory cell block; and
respectively disposing the first selected memory cell and the third selected memory cell in different memory cell blocks of the same first memory cell block, or disposing the third selected memory cell in a second memory cell block different from the first memory cell block.

10. A memory device, comprising:
a plurality of memory cell blocks;
a plurality of page buffers, respectively coupled to a plurality of global bit lines on the memory cell blocks; and
a controller, coupled to the memory cell blocks and the page buffers, wherein the controller is configured to:
apply a read voltage to a plurality of selected memory cells during a reading operation, where a plurality of sub-data generated according to write-in data are respectively stored in the selected memory cells; and
sense at least one read current generated by the selected memory cells, and generate readout data according to the at least one read current.

11. The memory device according to claim 10, wherein the sub-data have a same logic value.

12. The memory device according to claim 10, wherein the selected memory cells comprise a first selected memory cell and a second selected memory cell, the first selected memory cell and the second selected memory cell are disposed in a same memory cell sub-block of a same memory cell block, the first selected memory cell and the second selected memory cell are coupled to each other in series.

13. The memory device according to claim 12, wherein a page buffer of the page buffers corresponding to the first selected memory cell senses a first read current jointly provided by the first selected memory cell and the second selected memory cell, and determines the readout data to be a first logic value when the first read current is less than a first preset threshold.

14. The memory device according to claim 10, wherein the selected memory cells comprise a first selected memory cell and a second selected memory cell, the first selected memory cell and the second selected memory cell are respectively disposed in different memory cell sub-blocks of a same memory cell block.

15. The memory device according to claim 14, wherein the page buffers corresponding to the first selected memory cell and the second selected memory cell sense a first read current and a second read current respectively provided by the first selected memory cell and the second selected memory cell, and determine the readout data to be a second logic value when a sum of the first read current and the second read current is greater than a second preset threshold.

16. The memory device according to claim 10, wherein the selected memory cells comprise a first selected memory cell and a second selected memory cell, the first selected memory cell and the second selected memory cell are disposed in a same memory cell sub-block of a same memory cell block, and the first selected memory cell and the second selected memory cell are respectively coupled to different global bit lines.

17. The memory device according to claim 10, wherein the selected memory cells comprise a first selected memory cell and a second selected memory cell, the first selected memory cell and the second selected memory cell are respectively disposed in different memory cell blocks.

18. The memory device according to claim 10, wherein the selected memory cells comprise a first selected memory cell, a second selected memory cell, and a third selected memory cell, the first selected memory cell and the second selected memory cell are connected in series and disposed in a same memory cell sub-block of a same first memory cell block, the first selected memory cell and the third selected memory cell are respectively disposed in different memory cell blocks in the same first memory cell block, or the third selected memory cell is disposed in a second memory cell block different from the first memory cell block.

19. The memory device according to claim 10, wherein each of the memory cell blocks is a NAND flash memory cell block.
